(19) United States
(12) Patent Application Publication
(10) Pub. No.: US 2011/0177719 A1
(43) Pub. Date: Jul. 21, 2011

(54) Electrical connector module assembly

(75) Inventor: Galen M. Martin, Camp Hill, PA (US)

(73) Assignee: Tyco Electronics Corporation, Berwyn, PA (US)

(21) Appl. No.: 12/657,377

(22) Filed: Jan. 20, 2010

(51) Int. Cl. H01R 24/00; H05K 3/30

(52) U.S. Cl. 439/660; 29/832

(57) ABSTRACT

An electrical connector module assembly is disclosed having a connector header usable with multiple module bodies. At least one module body has integral alignment members for aligning printed circuit contact portions with the module body and with a connected substrate.

### BACKGROUND

The present embodiment relates to an electrical connector module assembly, and more particularly to a module assembly having a connector header which can have alternative uses.

It is quite common in the automotive industry to provide electronic control modules. Such modules are useful for controlling any of the engine functions, such as air fuel ratio, ignition, fuel injection, and the like. Typically, the modules include a module body or casing having a substrate positioned therein, where the substrate includes electronic components to control the various functions. The substrate could comprise a printed circuit board or flexible substrate. The substrate would include a connection mechanism adjacent to an edge thereof, where the connector is positioned adjacent an opening of the casing. The casing would thereafter be positionable adjacent to the engine, where the connector on the control module would complement a connector on the engine device to be monitored/controlled. The modules could be sealed or unsealed.

In some applications, it would be desirable to provide a connector assembly wherein a separable and discrete connector header is provided which may alternatively be used with a first or second module body.

### SUMMARY

In one embodiment, an electrical connector module assembly comprises a connector header having an insulative housing and a plurality of electrical terminals mounted therein. The electrical terminals having mating contact portions and printed circuit contact portions extending outwardly from the insulative housing. A module body defines an enclosure and has a module mating face and a connector header receiving area defined adjacent the module mating face. The header receiving area defines a receiving opening to receive the connector header and an alignment area to align the printed circuit contact portions.

In another embodiment described herein a method of manufacturing an electrical connector module assembly is described, comprising the steps of providing a connector header having an insulative housing and a plurality of electrical terminals mounted therein. The electrical terminals have mating contact portions and printed circuit contact portions extending outwardly from the insulative housing. A first module body is provided defining an enclosure and having a module mating face, and a connector header receiving area defined adjacent the module mating face. The header receiving area defines a receiving opening to receive the connector header and an alignment area to align the printed circuit contact portions. A second module body is provided which defines an enclosure. A printed circuit board is provided and the first or second module body is selected. The connector header is inserted into the selected module and the printed circuit contact portions are connected with associated contact members on the board.

### BRIEF DESCRIPTION OF DRAWINGS

FIG. 1 is a top perspective view of a first embodiment of an electrical connector module assembly;

FIG. 2 is a bottom perspective view of the electric connector module assembly of FIG. 1;

FIG. 3, is an exploded view of the electrical connector module assembly of FIG. 1;

FIG. 4 is a top perspective view of the connector header of the electrical connector module assembly;

FIG. 5 is a bottom perspective view of the connector header of the electrical connector module assembly;

FIG. 6 is a side view of the connector header of the electrical connector module assembly;

FIG. 7 is a rear perspective view of the connector header of the electrical connector module assembly;

FIG. 8 is an enlarged view of the section denoted in FIG. 7;

FIG. 9 is a top plan view of the inside of the module body of the electrical connector module assembly;

FIG. 10 is a bottom perspective view of the inside of the module body of the electrical connector module assembly;

FIG. 11 is an enlarged view of the section denoted in FIG. 10;

FIG. 12 is a bottom perspective view of the assembled module body and connector header;

FIG. 13 is an enlarged view of the section denoted in FIG. 12; and

FIG. 14 is an alternate embodiment using the connector header of FIGS. 4-8 with an alternate module body.

### DETAILED DESCRIPTION OF THE EMBODIMENTS

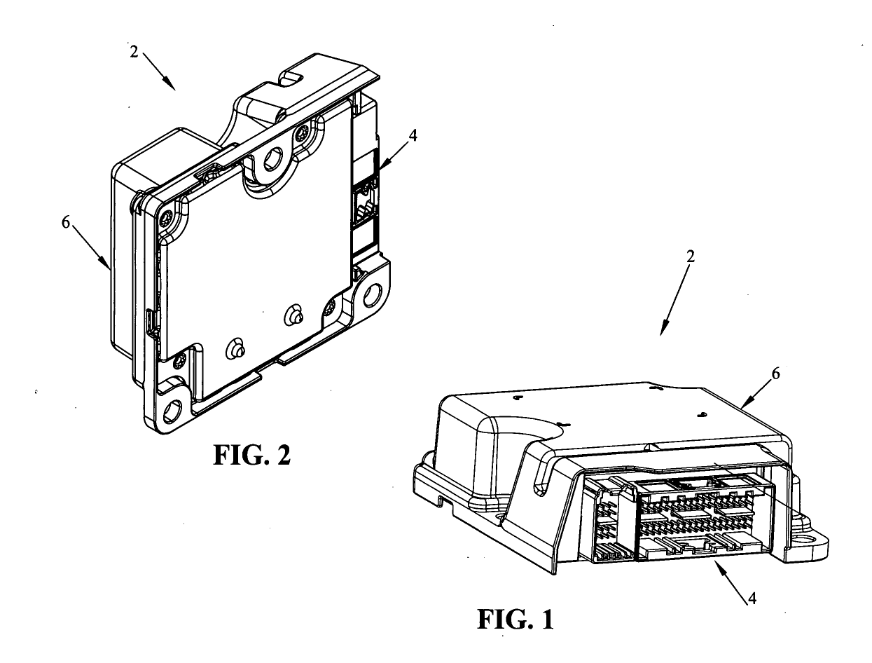

With reference first to FIGS. 1-3, an electrical connector module assembly is disclosed at 2, having a connector header 4, a module body 6, a substrate 8, shown here as a printed circuit board, and a cover 10. As shown, connector header 4 is comprised of an insulative housing 12 having a plurality of electrical terminals 14 mounted therein. The electrical terminals 14 comprise mating contact portions 16 and printed circuit contact portions 18. Substrate 8 also comprises contact areas 20 on substrate 8 which correspond in number and orientation with, printed circuit contact portion 18.

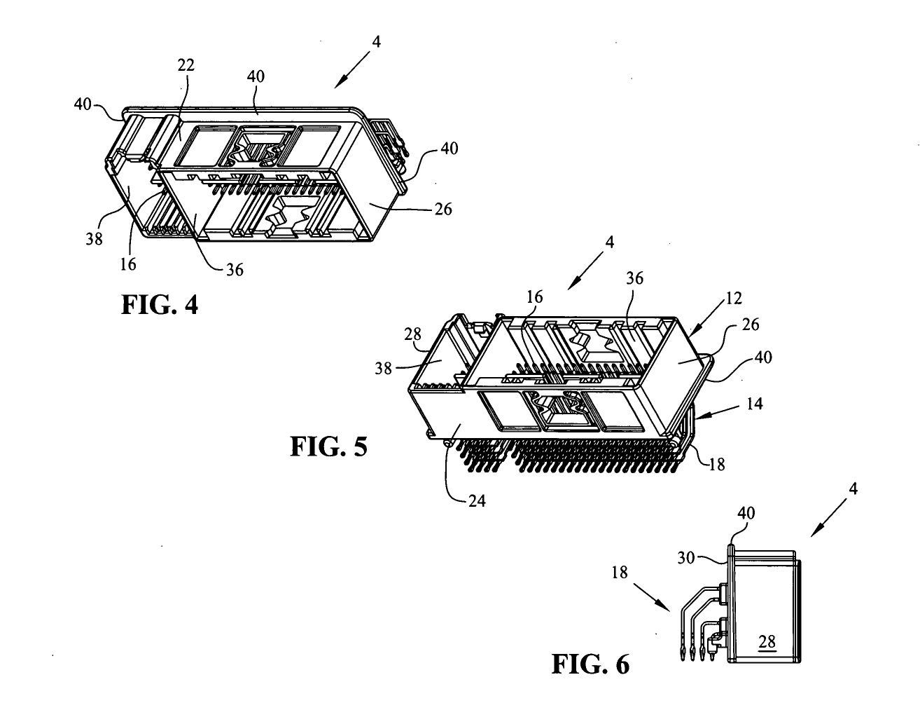

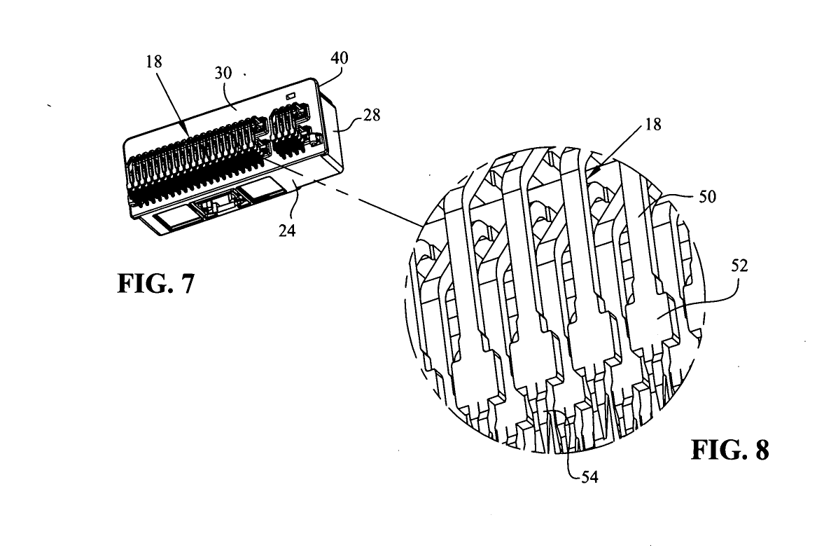

With reference now to FIGS. 4-8, connector header 4 will be described in greater detail. Connector header 4 has sidewalls 22, 24, end walls 26, 28 and rear wall 30, all of which define one or more cavities 36, 38. Electrical terminals extend through rear wall 30 such that mating contact portions 16 project into one or more cavities 36, 38 while printed circuit contact portions 18 extend rearwardly from rear wall 30. As shown, connector header 4 has plural rows of mating contact portions 16 and plural rows of printed circuit contact portions 18. As shown best in FIG. 6, the printed circuit contact portions 18 extend at a substantial right angle relative to the mating contact portions 16, with each row of mating contact portions having their corresponding printed circuit contact portions 18 extend over the previous row. A lip 40 extends substantially around top wall 22 and sidewalls 26, 28 and will define a portion of an alignment assembly as further defined herein. With reference now to FIGS. 7 and 8, printed circuit contact portions 18 are shown in greater detail. Each of the printed circuit contact portions 18 comprises a blade or tine portion 50, a cross bar 52 and a compliant pin portion 54.

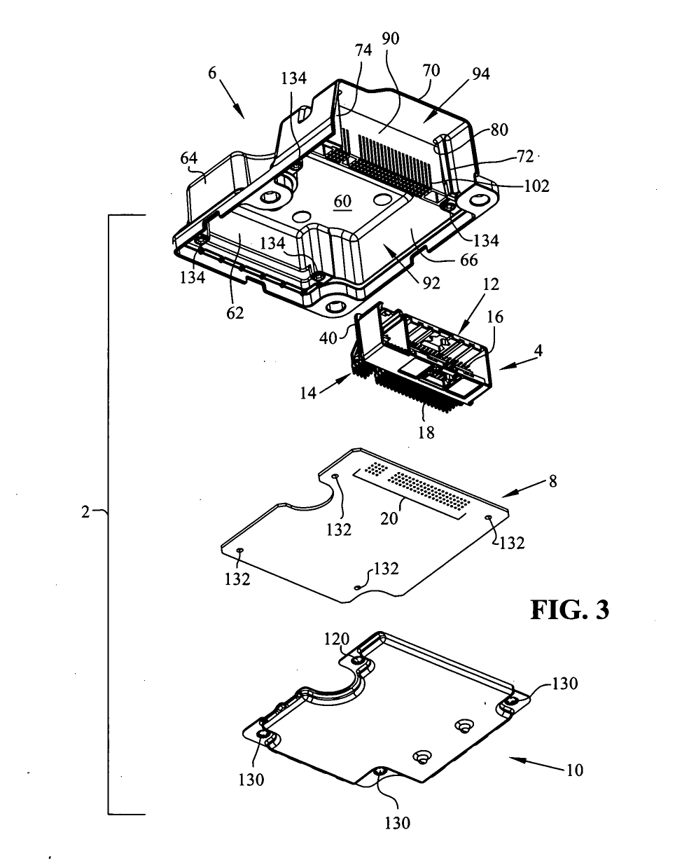

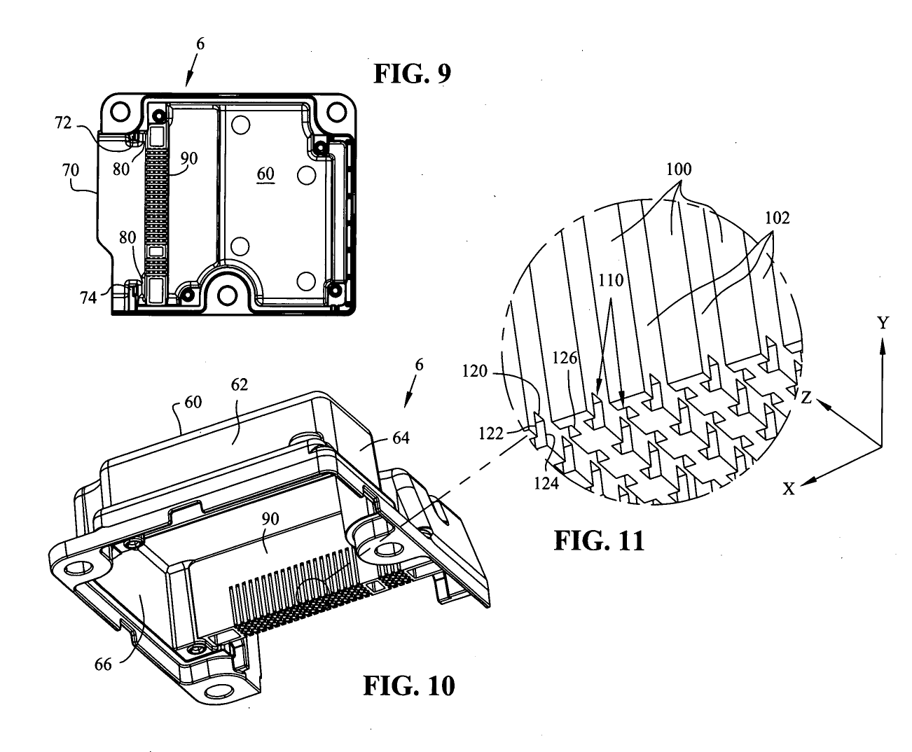

With reference now to FIGS. 9-11, module body 6 will be described in greater detail. Module body 6 comprises a top wall 60, end wall 62, sidewalls 64, 66 and with reference again to FIG. 3, a shroud 70. With reference to both FIGS. 3 and 9, module body 6 has alignment bars 72, 74 which define a slot 80. Alignment bars 72, 74 and lip 40 combine to define alignment assembly as more fully described herein. With reference still to FIG. 3, module 6 further includes a wall 90. As shown in FIG. 3, wall 90, sidewalls 64, 66, end wall 62 and top wall 60 combine to define an enclosure 92, whereas wall 90 extends laterally between sidewalls 64, 66 and spans the enclosure 92. Furthermore, wall 90, together with shroud 70 combine to define a connector header receiving area 94.

With reference now to FIGS. 10 and 11, wall 90 is shown as divided into a plurality of Columns 100 thereby defining intermediate spacings 102. It should be appreciated that the wall 90 could be separated laterally into a plurality of rows. However, given the configuration of connector header 4, and particularly the printed circuit contact portions 18, wall 90 defines individual columns 100. As shown, each of the spacings 102 have alignment members 110 flanking the spacing 102. The alignment members are defined by pairs of notches where each notch is defined by a top surface 120, side surfaces 122, 124, and end surfaces 126. Thus the alignment members 110 provide alignment in three dimensions; that is, in the x-direction by end surfaces 126, in the y-direction by top surface 120, and in the z-direction by side surfaces 122, 124.

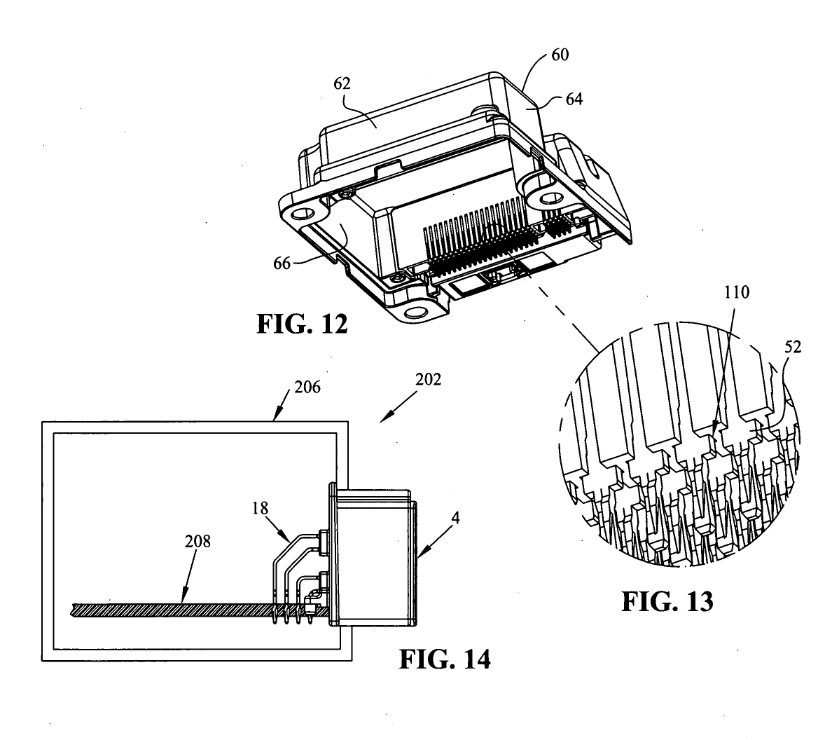

With reference again to FIG. 3, connector header 4 is shown exploded away from module body 6. Connector header 4 may be assembled to module body 6, by moving connector header 4 upwardly (as viewed in FIG. 3) such that lip 40 is positioned behind alignment bars 72, 74, (and into slot 80, FIG. 9) and with the individual printed circuit contact portions 18 aligned with the spacings 102. Thus, the same movement of the connector header 4 into alignment with the module body 6, also moves the printed circuit contact portions 18 into the spacings 102, and the cross bars 52 into corresponding alignment members 110. FIGS. 12 and 13 show the connector header 4 in the fully inserted position in the module body 6 with cross bars 52 in the fully inserted position within alignment members 110.

To complete the assembly of electrical connector module assembly 2, and with reference still to FIG. 3, substrate 8 would be positioned within module body 6, with contact areas 20 in connection with compliant pin portions 54. As shown, contact areas 20 are through holes, but any type of connection such as surface mount or other connection could be used. Cover 10 would now be positioned in place against module body 6, and over substrate 8, and fasteners (not shown) would be positioned through apertures 130 and 132, and into connection with bosses 134.

Alternatively, and with reference to FIG. 14, an alternate electrical connector module assembly 202 could be assembled using the same connector header 4, however with an alternate module body 206 and substrate 208. It should be appreciated that module body 206 is shown somewhat diagrammatically, and it should be understood that any configuration could be used for the module body 206.

While this invention has been described as having an exemplary design, the present invention may be further modified within the spirit and scope of this disclosure. The application is, therefore, intended to cover any variations, uses, or adaptations of the invention using its general principles. Further, this application is intended to cover such departures from the present disclosure as come within known or customary practice in the art to which this invention pertains.

What is claimed is:

1. An electrical connector module assembly, comprising:
a connector header having an insulative housing and a plurality of electrical terminals mounted therein, the electrical terminals having mating contact portions and printed circuit contact portions extending outwardly from the insulative housing; and
a module body defining an enclosure and having a module mating face, and a connector header receiving area defined adjacent the module mating face, the header receiving area defining a receiving opening to receive the connector header and an alignment area to align the printed circuit contact portions.

2. The electrical connector of claim 1, wherein the alignment area is defined by a wall which spans the enclosure.

3. The electrical connector of claim 2, wherein the wall is rearward of, and partially defines the connector header receiving area.

4. The electrical connector of claim 3, wherein the wall is separated to define columns or rows, with spacings therebetween, with the printed circuit contact portions being positioned within the spacings.

5. The electrical connector of claim 4, wherein the spacings are defined in axes parallel with a mating axis of the connector header, defining comb members.

6. The electrical connector of claim 5, wherein the connector header includes plural rows of mating contact portions and plural rows of printed circuit contact portions, the printed circuit contact portions extending at a substantial right angle relative to the mating contact portions, with each row of mating contact portions having the corresponding printed circuit contact portions extending over the previous row.

7. The electrical connector of claim 6, wherein the comb members comprise alignment members which align the printed circuit contact portions in three dimensions.

8. The electrical connector of claim 7, wherein the alignment members are defined by pairs of notches in the combs on opposite sides of the spacings.

9. The electrical connector of claim 8, wherein the connector header and the module body comprise alignment assembly, and the alignment assembly and the notches are defined such that the movement of the connector header into alignment with the module body, also moves the printed circuit contact portions into the notches.

10. The electrical connector of claim 9, wherein the printed circuit contact portions comprise cross bars which are received in the notches and the pairs of notches define stop surfaces in three dimensions.

11. A method of manufacturing an electrical connector module assembly, comprising the steps of:
providing a connector header having an insulative housing and a plurality of electrical terminals mounted therein, the electrical terminals having mating contact portions and printed circuit contact portions extending outwardly from the insulative housing;
providing a first module body defining an enclosure and having a module mating face, and a connector header receiving area defined adjacent the module mating face, the header receiving area defining a receiving opening to receive the connector header;
providing a second module body defining an enclosure;
providing a printed circuit board;
selecting the first or second module body; and
inserting the connector header into the selected module body and connecting the printed circuit contact portions with associated contact members on the board.

12. The method of claim 11, comprising the step of selecting the first module body, and inserting the connector header into the first module body prior to connecting the printed circuit contact portions with the associated contact members on the board.

13. The method of claim 12, further comprising the step of providing an alignment area to align the printed circuit contact portions, where the alignment area is defined by a wall which spans the enclosure.

14. The method of claim 13, wherein the wall is defined rearward of, and partially defines the connector header receiving area.

15. The method of claim 14, further comprising the step of separating the wall to define columns or rows, with spacings therebetween, and positioning the printed circuit contact portions within the spacings.

16. The method of claim 15, comprising the step of defining the spacings in axes parallel with a mating axis of the connector header, and defining comb members.

17. The method of claim 16, comprising the step of defining plural rows of mating contact portions and plural rows of printed circuit contact portions, with the printed circuit contact portions extending at a substantial right angle relative to the mating contact portions, with each row of mating contact portions having the corresponding printed circuit contact portions extending over the previous row.

18. The method of claim 17, comprising the step of defining alignment members on the comb members which align the printed circuit contact portions in three dimensions.

19. The method of claim 18, comprising the step of defining pairs of notches in the combs on opposite sides of the spacings as the alignment members.

20. The method of claim 19, comprising the steps of:
providing cross bars on the printed circuit contact portions;
providing an alignment assembly between the connector header and the first module body; and
moving the connector into alignment with the module body, and with the same movement, moving the cross bars into the notches.
